(19) United States
(12) Patent Application Publication
(10) Pub. No.: US 2026/0223621 A1
(43) Pub. Date: Jul. 30, 2026

(54) SUBSTRATE PROCESSING APPARATUS

(71) Applicant: SAMSUNG ELECTRONICS CO., LTD., SUWON-SI (KR)

(72) Inventors: Jihyun LEE, Suwon-si (KR); Dohyun JIN, Suwon-si (KR); Kyoungnoh KIM, Suwon-si (KR); Byoungsu KIM, Suwon-si (KR); Hyunjoo LEE, Suwon-si (KR)

(73) Assignee: SAMSUNG ELECTRONICS CO., LTD., SUWON-SI (KR)

(21) Appl. No.: 19/284,657

(22) Filed: Jul. 29, 2025

(30) Foreign Application Priority Data
Jan. 24, 2025 (KR) 10-2025-0011897

(51) Int. Cl. H01L 21/67; B08B 9/00; B08B 15/02; G03F 7/16

(52) U.S. Cl. CPC H10P 72/0402; B08B 9/00; B08B 15/02; G03F 7/16; H10P 72/0414

(57) ABSTRACT

A substrate processing apparatus includes a chamber, a substrate support arranged in a lower area of the chamber and configured to support a substrate, a discharge vessel, which is arranged in the lower area of the chamber to surround the substrate support and includes a bottom plate including a first exhaust port, an inner wall standing on an inner circumference of the bottom plate, and an outer wall standing on an outer circumference of the bottom plate, an inner cover arranged on the inner wall of the discharge vessel and including a guide plate at least partially covering a space of the discharge vessel, a first exhaust pipe connected to the first exhaust port of the discharge vessel, and a second exhaust port located closer to the center of the chamber than the first exhaust port in a plan view and arranged in a bottom wall of the chamber.

### CROSS-REFERENCE TO RELATED APPLICATION

This application is based on and claims priority under 35 U.S.C. § 119 to Korean Patent Application No. 10-2025-0011897, filed on Jan. 24, 2025, in the Korean Intellectual Property Office, the disclosure of which is incorporated by reference herein in its entirety.

### BACKGROUND

The inventive concept relates to a substrate processing apparatus, and more particularly, to a substrate processing apparatus including a processing vessel assembly.

To form a film, such as an insulating film or a photoresist film, on a substrate, such as a wafer, or to develop the photoresist film, a processing apparatus including a spin-coater is used. In general, a processing apparatus includes a chuck on which a substrate is mounted, a supply unit for supplying a processing liquid to the substrate, and a processing vessel for collecting a waste liquid, such as a processing liquid. When a semiconductor process is performed on a substrate by using a processing apparatus, fumes or gaseous contaminants generated from the substrate are discharged through an exhaust pipe connected to a processing vessel. However, there is an issue in that such contaminants are not discharged through the exhaust pipe and move to the lower portion of a processing vessel to deteriorate the reliability of a semiconductor process.

### SUMMARY

The inventive concept provides a substrate processing apparatus having improved reliability.

In addition, the inventive concept is not limited to the above aspect, and the above and other aspects of the inventive concept will be clearly understood by those of ordinary skill in the art from the following description.

According to an aspect of the inventive concept, there is provided a substrate processing apparatus including a chamber, a substrate support arranged in a lower area of the chamber and configured to support a substrate, a discharge vessel arranged in the lower area of the chamber to surround the substrate support and including a bottom plate, an inner wall, and an outer wall, the bottom plate including a first exhaust port, the inner wall standing on an inner circumference of the bottom plate, and the outer wall standing on an outer circumference of the bottom plate, an inner cover arranged on the inner wall of the discharge vessel and including a guide plate that covers at least a portion of a space of the discharge vessel, a first exhaust pipe connected to the first exhaust port of the discharge vessel, and a second exhaust port located closer to a center of the chamber than the first exhaust port in a plan view and arranged in a bottom wall of the chamber.

According to another aspect of the inventive concept, there is provided a substrate processing apparatus including a chamber, a substrate support arranged in a lower area of the chamber and configured to support a substrate, a discharge vessel arranged in the lower area of the chamber to surround the substrate support and including a bottom plate, an inner wall, and an outer wall, the bottom plate including a first exhaust port, the inner wall standing on an inner circumference of the bottom plate, and the outer wall standing on an outer circumference of the bottom plate, an inner cover arranged on the inner wall of the discharge vessel and including a guide plate that covers at least a portion of a space of the discharge vessel, an exhaust pipe connected to the exhaust port of the discharge vessel, and an exhaust hole arranged in the inner wall of the discharge vessel and connecting an inside of the discharge vessel and an outside of the discharge vessel to each other.

According to another aspect of the inventive concept, there is provided a substrate processing apparatus including a chamber, a substrate support arranged in a lower area of the chamber and configured to support a substrate, a discharge vessel arranged in the lower area of the chamber to surround the substrate support and including a bottom plate, an inner wall, and an outer wall, the bottom plate including a first exhaust port, the inner wall standing on an inner circumference of the bottom plate, and the outer wall standing on an outer circumference of the bottom plate, a first exhaust pipe connected to the first exhaust port of the discharge vessel, a second exhaust port located closer to a center of the chamber than the first exhaust port in a plan view and arranged in a bottom wall of the chamber, a second exhaust pipe connected to the second exhaust port of the bottom wall of the chamber, and an exhaust hole arranged in the inner wall of the discharge vessel and connecting an inside of the discharge vessel and an outside of the discharge vessel to each other.

### BRIEF DESCRIPTION OF THE DRAWINGS

Embodiments will be more clearly understood from the following detailed description taken in conjunction with the accompanying drawings in which:

FIG. 1 is a structural diagram schematically illustrating a substrate processing system including a substrate processing apparatus according to an embodiment;

FIG. 2 is a cross-sectional view illustrating a substrate processing apparatus according to an embodiment;

FIG. 3 is a plan view illustrating a chamber bottom wall and a discharge vessel according to an embodiment;

FIG. 4 is a cross-sectional view illustrating an inner wall of a discharge vessel according to an embodiment;

FIG. 5 is an enlarged cross-sectional view of an area in which a first exhaust hole and a second exhaust hole are located, according to an embodiment;

FIG. 6 is a plan view illustrating a chamber bottom wall and a discharge vessel according to an embodiment; and

FIG. 7 is a graph illustrating residence time of a gas in a lower space of a chamber in a Comparative Example and Examples.

### DETAILED DESCRIPTION OF THE EMBODIMENTS

Hereinafter, embodiments of the inventive concept will be described in detail with reference to the accompanying drawings. Like components are denoted by like reference numerals throughout the specification, and repeated descriptions thereof are omitted. In the drawings, the thickness or size of each layer may be exaggerated for convenience and clarity of descriptions, and thus, the shape and proportion of each layer may be somewhat different from the actual shape and actual proportion thereof.

Herein, terms indicating spatial positions, for example, “upper side”, “lower side”, “on”, “over”, “under”, and the like, are used to describe relative position relations between elements shown in the drawings, and it will be understood that such terms are used only for better understanding and are not to be construed in any way as limiting the inventive concept. Terms regarding spatially relative positions are intended to encompass changes according to directions of semiconductor devices in addition to directions illustrated in the drawings. That is, semiconductor devices may be oriented in various directions when used (or fabricated), and even in such cases, position-related terms used herein will be easily understood by those of ordinary skill in the art.

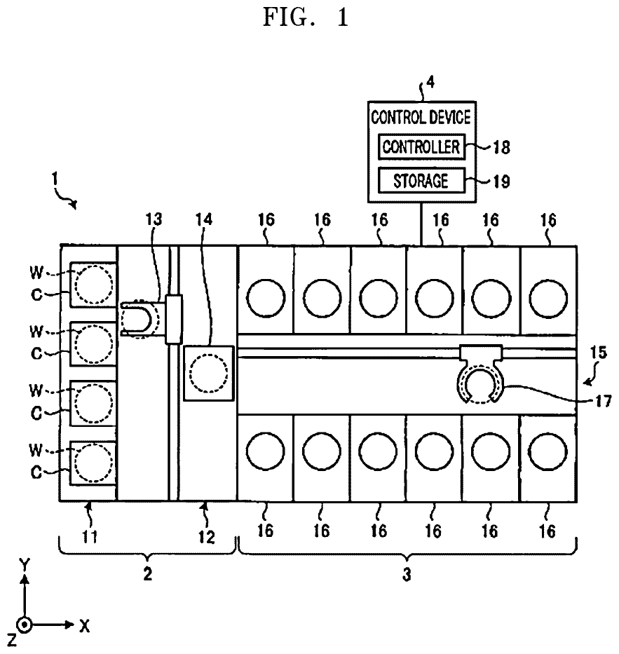

FIG. 1 is a structural diagram schematically illustrating a substrate processing system including a substrate processing apparatus according to an embodiment.

Referring to FIG. 1, a substrate processing system 1 may include a carrying in/out station 2 and a processing station 3. Here, the carrying in/out station 2 and the processing station 3 may be arranged adjacent to each other.

In an embodiment, a carrier arrangement unit 11 and a first conveying unit 12 may be provided to the carrying in/out station 2. A plurality of substrates W may be stacked in a vertical direction (a Z direction) in a carrier C in the carrier arrangement unit 1 1. The carrier C may include an airtight vessel, such as a Front Open Unified Pod (FOUP). The carrier C may be put on the carrier arrangement unit 11 by an operator or by a conveying means (not shown), such as an Overhead Transfer, an Overhead Conveyor, or an Automatic Guided Vehicle.

Here, a “substrate W” may refer to the substrate W itself or to a stack structure including the substrate W and a certain layer or film or the like formed on a surface of the substrate W. In addition, the “surface of the substrate W” may refer to an exposed surface of the substrate W itself or to an exposed surface of a certain layer or film or the like formed on the substrate W. For example, the substrate W may include a wafer or may include a wafer and at least one material film on the wafer. The material film may include an insulating film, a polymeric film, or the like formed on the wafer.

The first conveying unit 12 may convey the substrate W from the carrier C, in which the substrate W is received, to the processing station 3 and may cause the substrate W, on which processing has been completed by the processing station 3, to be received in the carrier C. The first conveying unit 12 may be mounted adjacent to the carrier arrangement unit 11 and may include a first substrate transport device 13 and a transfer unit 14.

A wafer holding device for holding the wafer W may be mounted in the first substrate transport device 13. The first substrate transport device 13 may be movable in a horizontal direction (an X direction and/or a Y direction) or the vertical direction (the Z direction) and may be pivotable around a vertical axis. In addition, the first substrate transport device 13 may transport the substate W between the carrier C and the transfer unit 14 by using the wafer holding device. The transfer unit 14 may provide a space for the substrate W carried in the processing station 3 and the substrate W carried out of the processing station 3 to temporarily stay in.

In an embodiment, the processing station 3 may be provided adjacent to the first conveying unit 12. The processing station 3 may include a second conveying unit 15 and a plurality of substrate processing apparatuses 16. Each of the plurality of substrate processing apparatuses 16 may be arranged on either side of the second conveying unit 15. A second substrate transport device 17 may be provided in the second conveying unit 15. A wafer holding device for holding the substrate W may be mounted in the second substrate transport device 17, like in the first substrate transport device 13. In addition, the second substrate transport device 17 may be movable in the horizontal direction (the X direction and/or the Y direction) and/or the vertical direction (the Z direction) and may be pivotable around the vertical axis. The second substrate transport device 17 may transport the substate W between the transfer unit 14 and a substrate processing apparatus 16 by using the wafer holding device. The substrate processing apparatus 16 may perform a substrate processing process on the substrate W transferred from the second substrate transport device 17.

Herein, a horizontal direction in which the second substrate transport device 17 moves along an axis may be defined as a first horizontal direction (the X direction), and a horizontal direction, which is orthogonal to the first horizontal direction (the X direction), and in which the first substrate transport device 13 moves along an axis, may be defined as a second horizontal direction (the Y direction). In addition, a direction orthogonal to the first horizontal direction (the X direction) and the second horizontal direction (the Y direction) may be defined as the vertical direction (the Z direction).

In addition, the substrate processing system 1 may include a control device 4. The control device 4 may be configured to control all operations of the substrate processing system 1. The control device 4 may include a controller 18 and a storage 19. The controller 18 may control operations of the substrate processing system 1 by reading and executing a program stored in the storage 19. The storage 19 may store a program for controlling various processing operations performed by the substrate processing system 1. The program stored in the storage 19 may be stored in a computer-readable recording medium and may be installed in the storage 19 of the control device 4 from the recording medium. Non-limiting examples of the computer-readable recording medium may include a hard disk (HD), a flexible disk (FD), a compact disk (CD), a magnet optical disk (MO), and/or a memory card.

In the substrate processing system 1 described above, the first substrate transport device 13 of the carrying in/out station 2 may unload the substrate W from the carrier C loaded on the carrier arrangement unit 11 first and then may load the unloaded substrate W on the transfer unit 14. After the substrate W is loaded on the transfer unit 14, the substrate W may be unloaded from the transfer unit 14 by the second substrate transport device 17 of the processing station 3 and may be carried into the substrate processing apparatus 16. After the substrate W carried into the substrate processing apparatus 16 is processed by the substrate processing apparatus 16, the substrate W may be carried out of the substrate processing apparatus 16 by the second substrate transport device 17 and may be loaded on the transfer unit 14. After the substrate W is loaded on the transfer unit 14, the substrate W may be returned to the carrier C on the carrier arrangement unit 11 by the first substrate transport device 13.

The substrate processing apparatus 16 may perform a semiconductor process on the substrate W. In an embodiment, the substrate processing apparatus 16 may include a coating apparatus, a development apparatus, a cleaning apparatus, and/or a chemical mechanical polishing (CMP) apparatus.

In an embodiment, when the substrate processing apparatus 16 includes a coating apparatus, the substrate processing apparatus 16 may be configured to dispense a coating material onto the substrate W. For example, the coating material may include a photosensitive film including a photoresist. For example, when the substrate processing apparatus 16 includes a development apparatus, the substrate processing apparatus 16 may be configured to dispense a development material onto the substrate W. For example, the development material may include tetramethylammonium hydroxide (TMAH) and/or KOH. In an embodiment, when the substrate processing apparatus 16 includes a cleaning apparatus, the substrate processing apparatus 16 may be configured to dispense a cleaning material onto the substrate W. For example, the cleaning material may include deionized water, isopropyl alcohol (IPA), a buffer solution, and/or a surfactant. In an embodiment, when the substrate processing apparatus 16 includes a CMP apparatus, the substrate processing apparatus 16 may be configured to dispense a slurry material onto the substrate W. For example, the slurry material may include polishing particles and/or a chemical reactant or the like.

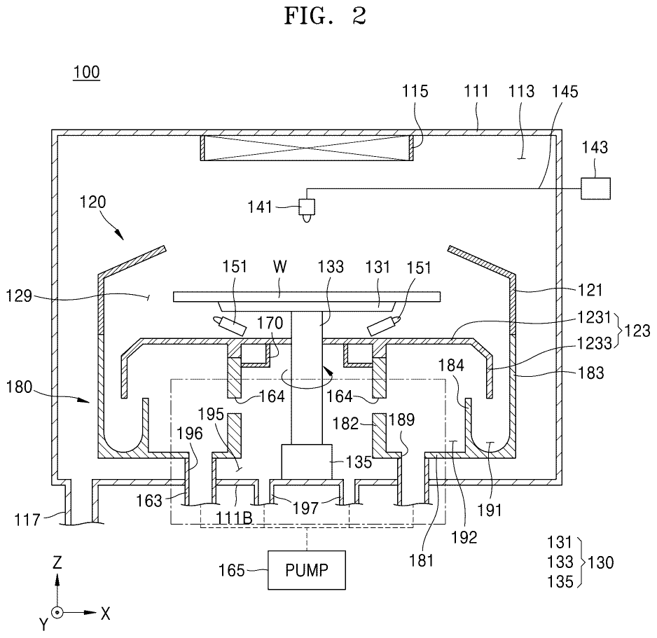

FIG. 2 is a cross-sectional view illustrating a substrate processing apparatus according to an embodiment.

Referring to FIG. 2, a substrate processing apparatus 100 may be configured to process the substrate W by supplying a processing liquid onto the substrate W. For example, the substrate processing apparatus 100 may be configured to form a material film on the substrate W. The substrate processing apparatus 100 of FIG. 2 may be an example of the substrate processing apparatus 16 of FIG. 1.

In an embodiment, the substrate processing apparatus 100 may be configured to form a photosensitive material film, such as a photoresist film, on the substrate W. In an embodiment, the substrate processing apparatus 100 may be configured to apply a developer onto a photosensitive material film, such as a photoresist film, on the substrate W. In an embodiment, the substrate processing apparatus 100 may be configured to remove impurities on the substrate W after a process is performed on the substrate W. For example, the substrate processing apparatus 100 may be configured to perform a spin-coating process and may be configured to perform the processes set forth above on the substrate W by performing the spin-coating process.

The substrate processing apparatus 100 may include a chamber 111, a processing vessel assembly 120, a substrate support 130, a processing liquid supply nozzle 141, and a cleaning nozzle 151.

The chamber 111 may provide an internal space 113 in which the substrate W is able to be processed. In an embodiment, a vacuum pressure or an atmospheric pressure may be formed in the internal space 113 of the chamber 111. The chamber 111 may include an opening. The substrate W may be carried in or out of the internal space 113 of the chamber 111 through the opening. To isolate the internal space 113 of the chamber 111 from an external environment, the opening of the chamber 111 may be sealed as needed.

A fan unit 115 may be mounted on an upper wall of the chamber 111. The fan unit 115 may be configured to blow a clean gas from an upper portion of the chamber 111 toward a lower portion of the chamber 111. An exhaust unit 117, which is configured to exhaust a gas in the chamber 111, may be arranged in the lower portion of the chamber 111. The exhaust unit 117 may be connected to an exhaust means, such as a vacuum pump, and may be configured to exhaust a gas in the chamber 111. A downdraft may be formed in the chamber 111 by the fan unit 115 and the exhaust unit 117.

The processing vessel assembly 120 may be used to collect and discharge a waste liquid. For example, while the substrate W is being processed by supplying a processing liquid onto the substrate W, the processing liquid flows out of the substrate W and falls into the processing vessel assembly 120. Such a waste liquid may be collected in the processing vessel assembly 120, and the collected waste liquid may be discharged out of the processing vessel assembly 120.

The processing vessel assembly 120 may be arranged in the internal space 113 of the chamber 111. The processing vessel assembly 120 may have a vessel shape having an opening formed in an upper portion thereof. The processing vessel assembly 120 may have a processing space 129 capable of accommodating the substrate support 130 and the substrate W loaded on the substrate support 130. The processing vessel assembly 120 may include an outer cover 121, an inner cover 123, and a discharge vessel 180. In an embodiment, the outer cover 121 may be referred to as an out-cup, the inner cover 123 may be referred to as an inner-cup, and the discharge vessel 180 may be referred to as an under-cup. In addition, the outer cover 121, the inner cover 123, and the discharge vessel 180 may be collectively referred to as a bowl. That is, the processing vessel assembly 120 may be referred to as a bowl. As described below in detail, a space defined by the chamber 111 and the processing vessel assembly 120 may be referred to as a lower space 195. The substrate processing apparatus 100 of the inventive concept has a configuration for effectively discharging a material remaining in the lower space 195 out of the chamber 111.

The outer cover 121 may be connected to an upper end of an outer wall 183 of the discharge vessel 180. The outer cover 121 may have a cylindrical shape surrounding the substrate W loaded on a spin chuck 131 of the substrate support 130. The outer cover 121 may extend upwards from the upper end of the outer wall 183 of the discharge vessel 180. For example, the outer cover 121 may extend from the upper end of the outer wall 183 of the discharge vessel 180 up to a vertical level that is higher than that of the substrate W supported by the substrate support 130.

In an embodiment, the outer cover 121 may include a vertical extension portion, which extends in the vertical direction (the Z direction) from the upper end of the outer wall 183 of the discharge vessel 180, and an inclined extension portion, which extends inwards from an upper end of the vertical extension portion while inclined upwards. The outer cover 121 may be configured to guide a processing liquid, which is scattered in a radial direction from the substrate W, to the discharge vessel 180. For example, the processing liquid scattered in the radial direction from the substrate W may collide with the outer cover 121 and then flow to a first space 191 of the discharge vessel 180 along an inner-wall surface of the outer cover 121. The processing liquid flowing out of the substrate W may flow along a first guide plate 1231 and may flow to the first space 191 of the discharge vessel 180 through a flow path between a second guide plate 1233 and the outer wall 183 of the discharge vessel 180. The processing liquid having moved to the discharge vessel 180 may be discharged to a liquid recovery pipe through a liquid discharge port formed in a bottom plate 181.

The inner cover 123 may be located at a vertical level that is lower than those of the spin chuck 131 and the substrate W supported by the spin chuck 131. The inner cover 123 may be coupled to the discharge vessel 180. The inner cover 123 may guide the processing liquid flowing out of the substrate W to flow to the first space 191 of the discharge vessel 180.

In an embodiment, the inner cover 123 may include the first guide plate 1231, which covers a second space 192 of the discharge vessel 180, and the second guide plate 1233, which extends downwards from an edge of the first guide plate 1231 toward the inside of the first space 191 of the discharge vessel 180.

The first guide plate 1231 may be connected to an upper end of an inner wall 182 of the discharge vessel 180. The first guide plate 1231 may extend outwards in the radial direction from the upper end of the inner wall 182 of the discharge vessel 180 to cover the second space 192 of the discharge vessel 180. The first guide plate 1231 may be spaced apart from a blocking wall 184 of the discharge vessel 180.

In an embodiment, the first guide plate 1231 may extend inwards in the radial direction so as to contact a rotary shaft 133 in the horizontal direction (the X direction and/or the Y direction). In another embodiment, the first guide plate 1231 may be spaced apart from the rotary shaft 133 in the horizontal direction (the X direction and/or the Y direction).

The second guide plate 1233 may extend downwards but may be spaced apart from the bottom plate 181 in the vertical direction (the Z direction). The second guide plate 1233 may have a ring shape in a plan view. The second guide plate 1233 may extend in the first space 191 of the discharge vessel 180 so as to be parallel to the blocking wall 184. The second guide plate 1233 may surround the blocking wall 184, and the outer wall 183 of the discharge vessel 180 may surround the second guide plate 1233. The second guide plate 1233 may be arranged between the blocking wall 184 and the outer wall 183 of the discharge vessel 180 to separate a flow path between the second guide plate 1233 and the blocking wall 184 from a flow path between the second guide plate 1233 and the outer wall 183. The second guide plate 1233 may extend downwards from the edge of the first guide plate 1231 toward the inside of the first space 191 of the discharge vessel 180 to form a curved flow path in the first space 191 of the discharge vessel 180.

The substrate support 130 may be arranged in the processing space 129 of the processing vessel assembly 120. The substrate support 130 may include the spin chuck 131, the rotary shaft 133, and a motor 135.

The spin chuck 131 may include a loading surface on which the substrate W is loaded. The spin chuck 131 may be configured to support the substrate W that is placed on the loading surface of the spin chuck 131. The upper surface of the spin chuck 131 may be provided in a substantially circular shape and may have a larger diameter than the substrate W. In an embodiment, the spin chuck 131 may be configured to support the substrate W by vacuum-sucking the substrate W. In an embodiment, the spin chuck 131 may be configured to support the substrate W by using electrostatic force.

The rotary shaft 133 may be configured to be rotated about the central axis thereof by an actuator (for example, the motor 135). The spin chuck 131 may be coupled to the rotary shaft 133 and may be configured to be rotated by the rotation of the rotary shaft 133. In addition, the spin chuck 131 may be configured to be elevated and lowered in the vertical direction (the Z direction). The motor 135 may rotate the rotary shaft 133 by performing a rotational motion. Therefore, the motor 135 may rotate the substrate W by rotating the spin chuck 131.

Although FIG. 2 illustrates an example in which the motor 135 is arranged inside the chamber 111, the inventive concept is not limited thereto. For example, the motor 135 may be arranged outside the chamber 111.

A processing liquid supply nozzle 141 may supply the processing liquid onto the substrate W. The processing liquid supply nozzle 141 may be arranged above the loading surface of the substrate support 130. The processing liquid supply nozzle 141 may be connected to a nozzle arm 145 and may be connected to a processing liquid source 143 via a flow path provided in the nozzle arm 145. The processing liquid supply nozzle 141 may receive the processing liquid, which is supplied from the processing liquid source 143, through the flow path of the nozzle arm 145. The processing liquid supply nozzle 141 may be configured to be moved by the nozzle arm 145. For example, the processing liquid supply nozzle 141 may be configured to move between a dispensing position for supplying the processing liquid onto the substrate W and a standby position spaced apart from the dispensing position.

In an embodiment, the processing liquid supply nozzle 141 may be configured to supply a photosensitive material, such as a photoresist, onto the substrate W. In an embodiment, the processing liquid supply nozzle 141 may be configured to supply a development material onto the substrate W to remove the photosensitive material. In an embodiment, the processing liquid supply nozzle 141 may be configured to supply a cleaning material onto the substrate W to remove impurities on the substrate W. In an embodiment, the processing liquid supply nozzle 141 may be configured to supply a slurry material for polishing a material on the substrate W onto the substrate W.

For example, while the spin chuck 131 is being rotated with the substrate W supported by the spin chuck 131, the processing liquid supply nozzle 141 may supply the processing liquid to the central portion of the substrate W. Because the spin chuck 131 is rotated, the processing liquid may move in the radial direction of the substrate W due to centrifugal force, and thus, the processing liquid may be applied on one whole surface of the substrate W.

In an embodiment, the substrate processing apparatus 100 may further include another nozzle configured to supply a material that is different from the processing liquid supplied through the processing liquid supply nozzle 141. For example, the substrate processing apparatus 100 may further include a nozzle configured to supply a solvent for performing an edge bead removal (EBR) process. When a photoresist film is formed on the substrate W by a spin-coating method, the thickness of the photoresist film coated on the edge portion of the substrate W may be relatively high. In this case, the nozzle may partially remove the photoresist film on the edge portion of the substrate W by supplying the solvent to the edge portion of the substrate W.

A cleaning nozzle 151 may be configured to supply a cleaning liquid to the processing space 129 of the processing vessel assembly 120. The cleaning nozzle 151 may be configured to dispense a cleaning liquid for removing contaminants, which remain in the processing vessel assembly 120, to the inside of the processing vessel assembly 120. For example, the cleaning nozzle 151 may be configured to receive the cleaning liquid for removing contaminants, which remain in the processing vessel assembly 120, from a cleaning liquid source and to dispense the cleaning liquid to the inside of the processing vessel assembly 120. For example, the cleaning liquid may include a thinner and/or acetone.

The cleaning nozzle 151 may be arranged in the processing vessel assembly 120. For example, the cleaning nozzle 151 may be arranged under the spin chuck 131 and may be configured to dispense the cleaning liquid to the backside surface of the substrate W on the substrate support 130 or to the inside of the processing vessel assembly 120. Although FIG. 2 illustrates an example in which two cleaning nozzles 151 are arranged in the processing vessel assembly 120, one cleaning nozzle 151 or three or more cleaning nozzles 151 may be arranged in the processing vessel assembly 120.

A flange 170 may be arranged on the lower surface of the first guide plate 1231. In a plan view, the flange 170 may be arranged closer to the center of the substrate support 130 than the discharge vessel 180. Heat in the substrate processing apparatus 100 may be controlled by supplying a cooling fluid to the inside of the flange 170. In addition, the flange 170 may support the first guide plate 1231.

In a plan view, the flange 170 may have a ring shape. One surface of the flange 170 may be in contact with the discharge vessel 180. For example, one surface of the flange 170 may be in contact with the inner wall 182 of the discharge vessel 180. In an embodiment, the flange 170 may be in contact with the lower surface of the first guide plate 1231 and/or the inner wall 182 of the discharge vessel 180. That is, the flange 170 may contact and support the first guide plate 1231.

The discharge vessel 180 may be arranged under the spin chuck 131 and may include a hollow portion in which the rotary shaft 133 is accommodated. The discharge vessel 180 may have a liquid accommodation space in which a waste liquid may be collected. In addition, the discharge vessel 180 may include an exhaust space separated or distinguished from the liquid accommodation space and may include a first exhaust port 189, which communicates with the exhaust space, and through which a gas is discharged. The first exhaust port 189 may be connected to a first exhaust pipe 163, and the first exhaust pipe 163 may be connected to an exhaust pump 165. The exhaust pump 165 may suck a gas in the discharge vessel 180 through the first exhaust pipe 163, thereby causing the gas in the discharge vessel 180 to be discharged to the first exhaust pipe 163. That is, a gas, together with a liquid such as the processing liquid, introduced into the discharge vessel 180 may be discharged out of the discharge vessel 180 through the first exhaust pipe 163. In an embodiment, a plurality of first exhaust pipes 163, for example, two to four first exhaust pipes 163, may be connected to the discharge vessel 180.

Although not shown in FIG. 2, the discharge vessel 180 may further include a liquid discharge port, which communicates with the liquid accommodation space, and through which a waste liquid is discharged. The liquid discharge port may be connected to a liquid recovery pipe, and the waste liquid collected in the discharge vessel 180 may be discharged to the liquid recovery pipe through the liquid discharge port and thus discharged out of the chamber 111.

The discharge vessel 180 may include the bottom plate 181, the inner wall 182, the outer wall 183, and the blocking wall 184.

The bottom plate 181 may include the first exhaust port 189. The inner wall 182, the outer wall 183, and the blocking wall 184 may stand on the bottom plate 181 in the vertical direction (the Z direction). The inner wall 182 may be arranged on or adjacent to an inner circumference of the bottom plate 181 and may extend upwards from the bottom plate 181. The outer wall 183 may be arranged on or adjacent to an outer circumference of the bottom plate 181 and may extend upwards from the bottom plate 181. The blocking wall 184 may be arranged between the outer wall 183 and the inner wall 182 and may extend upwards from the bottom plate 181. The blocking wall 184 may be arranged between the outer wall 183 and the inner wall 182 and may separate or distinguish the first space 191 between the blocking wall 184 and the outer wall 183 from the second space 192 between the blocking wall 184 and the inner wall 182.

Each of the inner wall 182, the outer wall 183, and the blocking wall 184 may have a ring shape in a plan view. In a plan view, the inner wall 182 may extend on the bottom plate 181 to surround the rotary shaft 133 of the substrate support 130, the blocking wall 184 may extend on the bottom plate 181 to surround the inner wall 182, and the outer wall 183 may extend on the bottom plate 181 to surround the blocking wall 184.

The first space 191 of the discharge vessel 180 may be a space defined by the bottom plate 181, the outer wall 183, and the blocking wall 184. The first space 191 of the discharge vessel 180 may be a liquid accommodation space, in which a waste liquid is collected, and may communicate with the liquid discharge port. The second space 192 of the discharge vessel 180 may be a space defined by the bottom plate 181, the inner wall 182, and the blocking wall 184. The second space 192 of the discharge vessel 180 may communicate with the first exhaust port 189 arranged in the bottom plate 181. A downdraft may be formed in the second space 192 of the discharge vessel 180 by an exhaust pressure generated by the exhaust pump 165. A gas introduced into the first space 191 of the discharge vessel 180 may climb over the blocking wall 184 to flow in the second space 192, and then, may be discharged to the first exhaust pipe 163 through the first exhaust port 189. Because the second space 192 of the discharge vessel 180 is separated from the first space 191, in which a waste liquid is collected, of the discharge vessel 180 by the blocking wall 184, a gas and a liquid may be discharged while separated from each other in the discharge vessel 180.

In the internal space 113 of the chamber 111, the lower space 195 may be defined by a bottom wall 111B of the chamber 111, the first guide plate 1231, the first exhaust pipe 163, and the discharge vessel 180.

The bottom wall 111B of the chamber 111 may include a second exhaust port 196, which communicates with the lower space 195, and through which a material in the lower space 195 is discharged. The second exhaust port 196 may be arranged closer to the center of the substrate support 130 than the first exhaust port 189. In an embodiment, the second exhaust port 196 may not overlap the discharge vessel 180 in the vertical direction (the Z direction). In another embodiment, at least a portion of the second exhaust port 196 may overlap at least a portion of the discharge vessel 180 in the vertical direction (the Z direction).

The second exhaust port 196 may be connected to a second exhaust pipe 197. The second exhaust pipe 197 may be connected to the exhaust pump 165. The exhaust pump 165 may suck a material in the lower space 195 through the second exhaust pipe 197, thereby causing the material in the lower space 195 to be easily discharged to the second exhaust pipe 197. In an embodiment, the cross-section of the second exhaust port 196 may have a circular shape. In another embodiment, the cross-section of the second exhaust port 196 may have an elliptical shape, a polygonal shape, and/or an atypical shape.

In addition, an exhaust hole 164, through which a gas in the lower space 195 is discharged, may be formed in the inner wall 182, the exhaust hole 164 connecting the lower space 195 and the second space 192 to each other. In an embodiment, the cross-section of the exhaust hole 164 may have a circular shape. In another embodiment, the cross-section of the exhaust hole 164 may have an elliptical shape, a polygonal shape, and/or an atypical shape.

A gas in the lower space 195 may move to the first exhaust pipe 163 through the exhaust hole 164. As described above, the first exhaust pipe 163 may be connected to the exhaust pump 165. The exhaust pump 165 may suck a material in the lower space 195 through the first exhaust pipe 163, thereby causing the material in the lower space 195 to be easily discharged to the first exhaust pipe 163. In an embodiment, the exhaust hole 164 may be located at a vertical level that is lower than that of the flange 170. When the exhaust hole 164 is located at a vertical level that is higher than that of the flange 170, a material discharged from the substrate W may be introduced into the second space 192.

In a general substrate processing apparatus, a path, via which a gas remaining in a lower space under a processing vessel assembly moves to the outside of a chamber, is limited. Therefore, because the time for the gas to stay in the lower space is increased and the time for the gas to contact a component of the substrate processing apparatus is increased, the substrate processing apparatus has low reliability.

The substrate processing apparatus 100 of the inventive concept may provide a path allowing a material in the lower space 195 to be effectively discharged out of the chamber 111. Therefore, the degree, by which a component of the substrate processing apparatus 100 is in contact with the gas, may be reduced, thereby improving the mechanical reliability of the substrate processing apparatus 100.

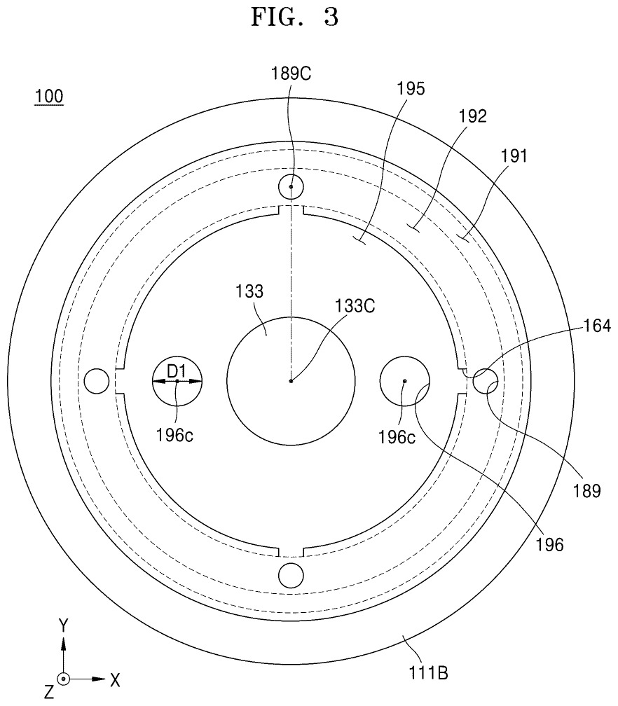

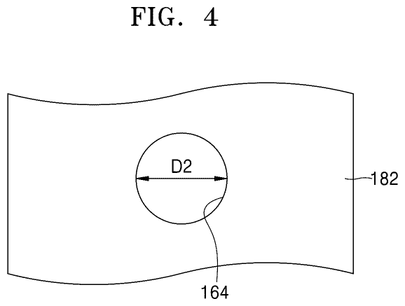

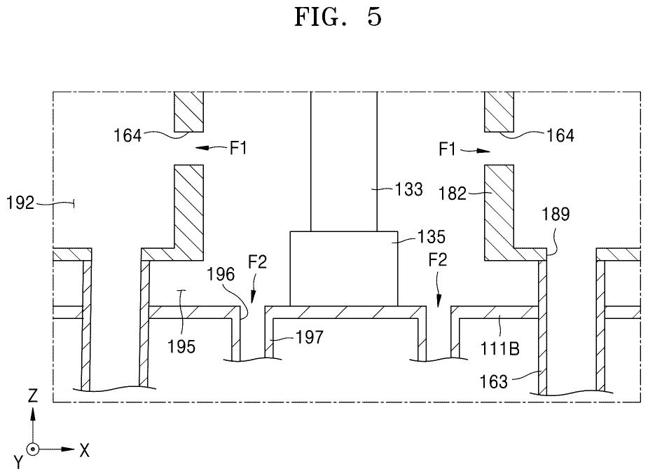

FIG. 3 is a plan view illustrating a chamber bottom wall and a discharge vessel according to an embodiment. FIG. 4 is a cross-sectional view illustrating an inner wall of a discharge vessel according to an embodiment. FIG. 5 is an enlarged cross-sectional view of an area in which a first exhaust hole and a second exhaust hole are located, according to an embodiment. In FIG. 4, for convenience of description, the motor 135 is omitted. Descriptions are made with further reference to FIG. 2.

Referring to FIGS. 3 to 5, the exhaust hole 164 may connect the second space 192 of the discharge vessel 180 and the lower space 195 to each other. That is, the exhaust hole 164 may provide a path via which a gas in the lower space 195 moves to the second space 192. More specifically, the gas in the lower space 195 may flow to the second space 192 through the exhaust hole 164, as shown by a first flow direction F1 in FIG. 5.

The second exhaust port 196 may connect the lower space 195 to the outside of the chamber 111. That is, the second exhaust port 196 may provide a path via which a gas in the lower space 195 moves to the outside of the chamber 111. More specifically, the gas in the lower space 195 may flow to the outside of the chamber 111 through the second exhaust port 196, as shown by a second flow direction F2 in FIG. 5.

The second exhaust port 196 may have a first diameter D1, and the exhaust hole 164 may have a second diameter D2. In an embodiment, the first diameter D1 of the second exhaust port 196 may be about 10 mm to about 30 mm. In an embodiment, the second diameter D2 of the exhaust hole 164 may be about 5 mm to about 20 mm.

In a plan view, the exhaust hole 164 may be arranged on an imaginary straight line connecting a center 196C of at least one second exhaust port 196 from among a plurality of second exhaust ports 196 to the center of the substrate support 130. Although FIG. 3 illustrates only the rotary shaft 133 and a center 133C of the rotary shaft 133, the center 133C of the rotary shaft 133 may be consistent with the center of the substrate support 130 in a plan view.

Although FIG. 3 illustrates an example in which the substrate processing apparatus 100 includes two second exhaust ports 196 and four exhaust holes 164, the inventive concept is not limited thereto. For example, the substrate processing apparatus 100 may include one second exhaust port 196 or three or more second exhaust ports 196. In addition, for example, the substrate processing apparatus 100 may include three or less exhaust holes 164 or five or more exhaust holes 164.

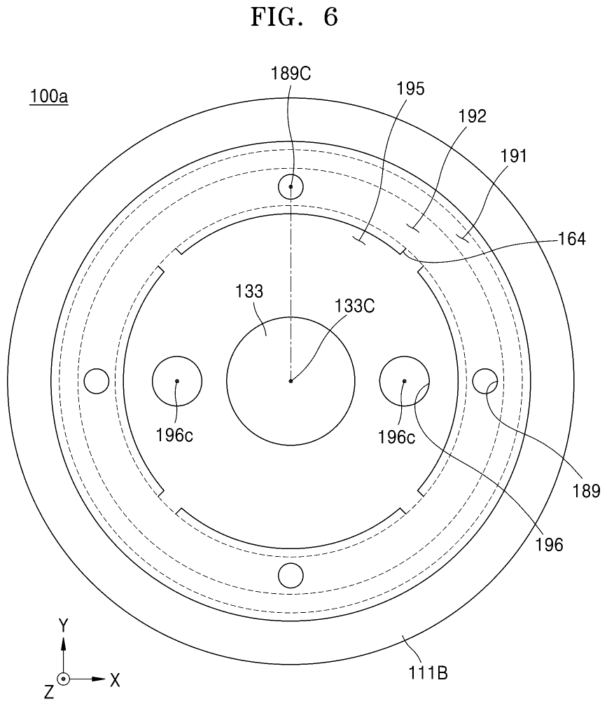

FIG. 6 is a plan view illustrating a chamber bottom wall and a discharge vessel according to an embodiment. In FIG. 6, for convenience of description, the motor 135 is omitted. Descriptions are made with further reference to FIGS. 2 and 3.

A substrate processing apparatus 100a of FIG. 6 includes an exhaust hole 164 and a second exhaust port 196. Because the substrate processing apparatus 100a of FIG. 6 is substantially the same as the substrate processing apparatus 100 of FIG. 3 except for relative positions of the exhaust hole 164 and the second exhaust port 196, the relative positions of the exhaust hole 164 and the second exhaust port 196 are mainly described.

Referring to FIG. 6, the substrate processing apparatus 100a may include the second exhaust port 196, which connects the lower space 195 to the outside of the chamber 111, and the exhaust hole 164, which connects the second space 192 of the discharge vessel 180 to the lower space 195.

In a plan view, the exhaust hole 164 may not be arranged on an imaginary straight line connecting the center 196C of at least one second exhaust port 196 from among a plurality of second exhaust ports 196 to the center of the substrate support 130. Although FIG. 6 illustrates only the rotary shaft 133 and the center 133C of the rotary shaft 133, the center 133C of the rotary shaft 133 may be consistent with the center of the substrate support 130 in a plan view.

For example, a first line segment, which connects the center 196C of at least one second exhaust port 196 from among the plurality of second exhaust ports 196 to the center of the substrate support 130, and a second line segment, which connects the center of at least one exhaust hole 164 from among a plurality of exhaust holes 164 to the center of the substrate support 130, may form an angle that is different from 0° or 180°. For example, although the first line segment and the second line segment may form an angle of about 45° or about 135°, the inventive concept is not limited thereto, and the first line segment and the second line segment may form various angles.

Although FIG. 6 illustrates an example in which the substrate processing apparatus 100a includes four exhaust holes 164 and two exhaust ports 196, the inventive concept is not limited thereto. For example, the substrate processing apparatus 100a may include three or less exhaust holes 164 or five or more exhaust holes 164. In addition, the substrate processing apparatus 100a may include one exhaust port 196 or three or more exhaust ports 196.

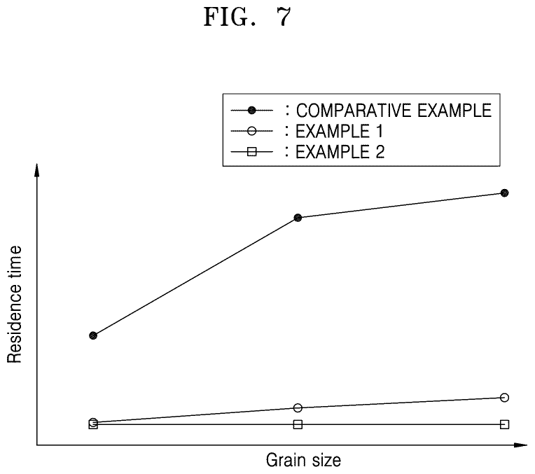

FIG. 7 is a graph illustrating residence time of a gas in a lower space of a chamber in a Comparative Example and Examples. FIG. 7 is a graph showing the effects of Examples of the inventive concept. The horizontal axis of the graph represents a grain size of the gas, and the vertical axis of the graph represents residence time. Each of the horizontal axis and the vertical axis of the graph is represented by an arbitrary unit (that is, a.u.). The Comparative Example indicates a substrate processing apparatus not including the exhaust hole 164 and the second exhaust port 196. Example 1 indicates the substrate processing apparatus 100 including the second exhaust port 196, and Example 2 indicates the substrate processing apparatus 100 including the exhaust hole 164. Descriptions are made with further reference to FIGS. 1 to 6.

Referring to FIG. 7, the residence time of the gas in the lower space 195 may be reduced in Examples 1 and 2 as compared with the Comparative Example. In all ranges of grain size data, the residence time of the gas in the lower space in the Comparative Example is significantly longer than the residence time of the gas in the lower space 195 in each of Examples 1 and 2. For example, the residence time of the gas in the lower space in the Comparative Example may be about 8 or more times the residence time of the gas in the lower space 195 in each of Examples 1 and 2. Therefore, as described above, the substrate processing apparatus 100 may provide a path via which the gas in the lower space 195 is discharged, thereby improving the reliability of the substrate processing apparatus 100.

While the inventive concept has been particularly shown and described with reference to embodiments thereof, it will be understood that various changes in form and details may be made therein without departing from the spirit and scope of the following claims.

What is claimed is:

1. A substrate processing apparatus comprising:
a chamber;
a substrate support arranged in a lower area of the chamber and supporting a substrate;
a discharge vessel arranged in the lower area of the chamber to surround the substrate support and comprising a bottom plate, an inner wall, and an outer wall, the bottom plate comprising a first exhaust port, the inner wall standing on an inner circumference of the bottom plate, and the outer wall standing on an outer circumference of the bottom plate;
an inner cover arranged on the inner wall of the discharge vessel and comprising a guide plate that covers at least a portion of a space of the discharge vessel;
a first exhaust pipe connected to the first exhaust port of the discharge vessel; and
a second exhaust port located closer to a center of the chamber than the first exhaust port in a plan view and arranged in a bottom wall of the chamber.

2. The substrate processing apparatus of claim 1, further comprising a second exhaust pipe connected to the second exhaust port.

3. The substrate processing apparatus of claim 2, wherein the second exhaust pipe is connected to an exhaust pump.

4. The substrate processing apparatus of claim 1, wherein the second exhaust port has a circular shape.

5. The substrate processing apparatus of claim 1, wherein the second exhaust port does not overlap the discharge vessel in a vertical direction of substrate processing apparatus.

6. The substrate processing apparatus of claim 1, wherein the second exhaust port has a diameter of about 10 mm to about 30 mm.

7. The substrate processing apparatus of claim 1, further comprising a processing liquid supply nozzle configured to supply a processing liquid toward the substrate that is supported by the substrate support.

8. A substrate processing apparatus comprising:
a chamber;
a substrate support arranged in a lower area of the chamber and supporting a substrate;
a discharge vessel arranged in the lower area of the chamber to surround the substrate support and comprising a bottom plate, an inner wall, and an outer wall, the bottom plate comprising an exhaust port, the inner wall standing on an inner circumference of the bottom plate, and the outer wall standing on an outer circumference of the bottom plate;
an inner cover arranged on the inner wall of the discharge vessel and comprising a guide plate that covers at least a portion of a space of the discharge vessel;
an exhaust pipe connected to the exhaust port of the discharge vessel; and
an exhaust hole arranged in the inner wall of the discharge vessel and connecting an inside of the discharge vessel and an outside of the discharge vessel to each other.

9. The substrate processing apparatus of claim 8, wherein the discharge vessel further comprises a blocking wall standing on the bottom plate to separate a first space and a second space from each other, the first space fluidically communicating with the exhaust port, and the second space being spaced apart from the exhaust port, and
the exhaust hole connects the first space of the discharge vessel to the outside of the discharge vessel.

10. The substrate processing apparatus of claim 8, wherein, in a plan view, the guide plate extends toward a center of the substrate support,
the substrate processing apparatus further comprises a flange arranged outside the discharge vessel so as to be adjacent to a lower surface of the guide plate and the inner wall of the discharge vessel, the flange contacting and supporting the guide plate, and
the exhaust hole is located at a vertical level that is lower than a level of the flange.

11. The substrate processing apparatus of claim 8, wherein the exhaust hole has a circular shape.

12. The substrate processing apparatus of claim 8, wherein, in a plan view, the exhaust hole is arranged on an imaginary straight line connecting a center of the substrate support to a center of the exhaust port.

13. The substrate processing apparatus of claim 8, wherein, in a plan view, the exhaust hole is not arranged on an imaginary straight line connecting a center of the substrate support to a center of the exhaust port.

14. The substrate processing apparatus of claim 8, wherein the exhaust hole has a diameter of about 5 mm to about 20 mm.

15. The substrate processing apparatus of claim 8, further comprising:
a processing liquid supply nozzle configured to supply a processing liquid toward the substrate that is supported by the substrate support,
wherein the processing liquid supply nozzle is configured to supply at least one of a development material, a photosensitive material, and a cleaning material, which are in a liquid state, onto the substrate.

16. The substrate processing apparatus of claim 8, further comprising an outer cover connected to an upper end of the outer wall of the discharge vessel and extending upwards from the upper end of the outer wall of the discharge vessel.

17. A substrate processing apparatus comprising:
a chamber;
a substrate support arranged in a lower area of the chamber and supporting a substrate;
a discharge vessel arranged in the lower area of the chamber to surround the substrate support and comprising a bottom plate, an inner wall, and an outer wall, the bottom plate comprising a first exhaust port, the inner wall standing on an inner circumference of the bottom plate, and the outer wall standing on an outer circumference of the bottom plate;
a first exhaust pipe connected to the first exhaust port of the discharge vessel;
a second exhaust port located closer to a center of the chamber than the first exhaust port in a plan view and arranged in a bottom wall of the chamber;
a second exhaust pipe connected to the second exhaust port of the bottom wall of the chamber; and
an exhaust hole arranged in the inner wall of the discharge vessel and connecting an inside of the discharge vessel and an outside of the discharge vessel to each other.

18. The substrate processing apparatus of claim 17, further comprising:
a processing liquid supply nozzle configured to supply a processing liquid toward the substrate that is supported by the substrate support; and
an outer cover connected to an upper end of the outer wall of the discharge vessel and extending upwards from the upper end of the outer wall of the discharge vessel.

19. The substrate processing apparatus of claim 17, wherein each of the first exhaust pipe and the second exhaust pipe is connected to an exhaust pump.

20. The substrate processing apparatus of claim 17, further comprising at least one of a coating apparatus, a development apparatus, a cleaning apparatus, and a chemical mechanical polishing (CMP) apparatus.
